(19) United States
(12) Patent Application Publication
(10) Pub. No.: US 2024/0107659 A1
(43) Pub. Date: Mar. 28, 2024

(54) CIRCUIT BOARD AND ELECTRONIC COMPONENT

(71) Applicant: Murata Manufacturing Co., Ltd., Nagaokakyo-shi (JP)

(72) Inventor: Kenji MATSUDA, Nagaokakyo-shi (JP)

(21) Appl. No.: 18/525,949

(22) Filed: Dec. 1, 2023

Related U.S. Application Data
(63) Continuation of application No. PCT/JP2022/021948, filed on May 30, 2022.

(30) Foreign Application Priority Data
Jul. 13, 2021 (JP) 2021-115774

(51) Int. Cl. H05K 1/02; H05K 1/03; H05K 1/11; H05K 1/18

(52) U.S. Cl. CPC H05K 1/0213; H05K 1/0313; H05K 1/11; H05K 1/181

(57) ABSTRACT

A circuit board includes a substrate, a first mounting conductor, a first ground conductor, a first floating conductor, a signal line conductor, and a connection conductor. The first mounting conductor is on a surface of the substrate and includes a first external connection conductor. The first ground conductor is positioned on the substrate opposite to the first mounting conductor. The floating conductor is between the first mounting conductor and the first ground conductor. The signal line conductor is inside the substrate. The connection conductor connects the first mounting conductor and the signal line conductor. When viewed in a thickness direction of the substrate, the signal line conductor and the connection conductor are each provided at a position different from the first external connection conductor, and the floating conductor overlaps an entirety or substantially an entirety of the first external connection conductor.

### CROSS REFERENCE TO RELATED APPLICATIONS

This application claims the benefit of priority to Japanese Patent Application No. 2021-115774 filed on Jul. 13, 2021 and is a Continuation Application of PCT Application No. PCT/JP2022/021948 filed on May 30, 2022. The entire contents of each application are hereby incorporated herein by reference.

### BACKGROUND OF THE INVENTION

### 1. Field of the Invention

The present invention relates to a circuit board, and an electronic component.

### 2. Description of the Related Art

An example of a circuit board is a semiconductor device mounting board disclosed in Japanese Unexamined Patent Application Publication No. 2007-227757. For example, Japanese Unexamined Patent Application Publication No. 2007-227757 discloses a semiconductor device mounting board including a pad, an internal conductor layer, and a conductor. The pad is provided for connection to an external circuit board. The internal conductor layer is adjacent to the pad, and includes an opening located opposite to the pad. The conductor is disposed inside the opening of the internal conductor layer. The conductor is electrically isolated and floating from other conductors.

The board illustrated in Japanese Unexamined Patent Application Publication No. 2007-227757 includes a region where no conductor is present. In the direction of the plane of the board, the region is located between a floating conductor, which is a conductor electrically isolated and floating from other conductors, and a signal conductor or a signal land. When viewed in the thickness direction of the board, a portion of the board that overlaps the region may have decreased flatness. In particular, a decrease in the flatness of a portion of the board that connects to the external circuit board may lead to poor connection with the external circuit board. That is, due to the presence of the region with no conductor between the floating conductor and a conductor connected to a mounting conductor, the mounting conductor, in particular, a plating conductor may have decreased flatness.

### SUMMARY OF THE INVENTION

A circuit board according to a preferred embodiment of the present invention includes a substrate, a first mounting conductor, a first ground conductor, a floating conductor, a signal line conductor, and a connection conductor. The first mounting conductor is located on a surface of the substrate and includes a first external connection conductor. The first ground conductor is located on the substrate. The first ground conductor is located opposite to the first mounting conductor. The floating conductor is between the first mounting conductor and the first ground conductor. The signal line conductor is inside the substrate. The connection conductor connects the first mounting conductor and the signal line conductor to each other. When viewed in a thickness direction of the substrate, the signal line conductor and the connection conductor are each provided at a position different from the first external connection conductor, and the floating conductor overlaps an entirety or substantially an entirety of the first external connection conductor.

Preferred embodiments of the present invention make it possible to reduce a decrease in the flatness of a plating conductor.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is an exploded top view of a circuit board 100 according to a preferred embodiment of the present invention.

FIG. 2 is a partial cross-sectional view of the circuit board 100.

FIG. 3 is a cross-sectional view of the circuit board 100.

FIG. 4 is a partial enlarged view of the circuit board 100.

FIG. 5 is a partial enlarged view of a circuit board 101 according to a preferred embodiment of the present invention.

FIG. 6 is a partial cross-sectional view of an electronic component 300 according to a preferred embodiment of the present invention.

FIG. 7 is a partial cross-sectional view of an electronic component 301 according to a preferred embodiment of the present invention.

FIG. 8 is a partial cross-sectional view of the electronic component 301.

FIG. 9 is a partial cross-sectional view of an electronic component 302 according to a preferred embodiment of the present invention.

FIG. 10 is a partial cross-sectional view of an electronic component 303 according to a preferred embodiment of the present invention.

FIG. 11 is a partial cross-sectional view of a circuit board 106 according to a preferred embodiment of the present invention.

### DETAILED DESCRIPTION OF THE PREFERRED EMBODIMENTS

Preferred embodiments of the present invention are described below with reference to the drawings by way of several specific examples. Throughout the drawings, the same reference signs are used to designate the same or corresponding portions and features. Although separate preferred embodiments are herein described for convenience in consideration of ease of explanation or understanding of the main scope of the invention, features described in different preferred embodiments can be replaced or combined with each other. In second and subsequent preferred embodiments and modifications, matters the same or substantially the same as those in the first preferred embodiment are not described in further detail, and only differences from the first preferred embodiment are described. In particular, the same or similar advantageous operational effects provided by the same or similar features are not described for each individual preferred embodiment.

### First Preferred Embodiment

Structure of Circuit Board

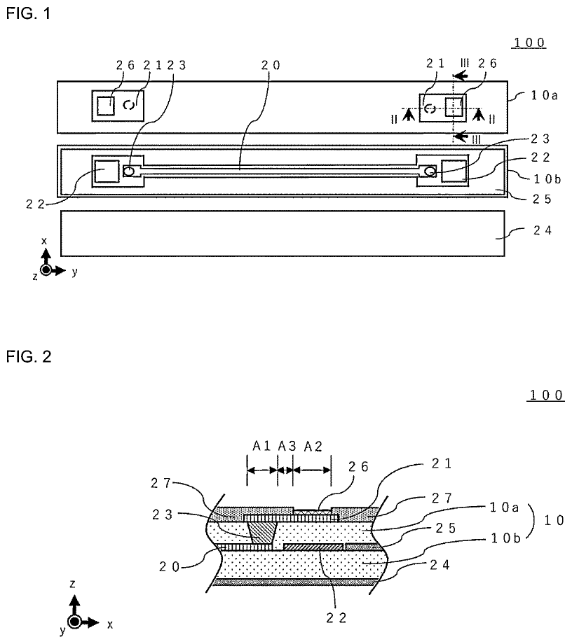

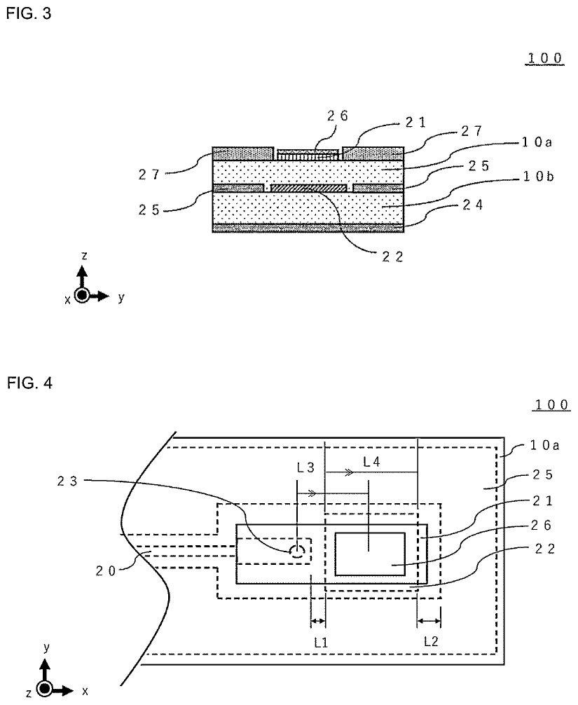

The structure of a circuit board 100 according to a first preferred embodiment of the present invention is described below with reference to the drawings. FIG. 1 is an exploded top view of the circuit board 100. FIG. 2 is a partial cross-sectional view of the circuit board 100. More specifically, FIG. 2 is a cross-sectional view taken along a line II-II in FIG. 1. FIG. 3 is a cross-sectional view of the circuit board 100. More specifically, FIG. 3 is a cross-sectional view taken along a line III-III in FIG. 1. FIG. 4 is a partial enlarged view centered around a first mounting conductor 21 of the circuit board 100.

First, the structure of the circuit board 100 is described with reference to FIGS. 1, 2, and 3. The circuit board 100 transmits a radio-frequency signal. The circuit board 100 is used in an electronic apparatus such as a smartphone, for example, to electrically connect two circuits to each other. As illustrated in FIGS. 1 and 2, the circuit board 100 includes a substrate 10, a signal line conductor 20, a first mounting conductor 21, a first floating conductor 22, a connection conductor 23, and a first ground conductor 24. Although the circuit board 100 according to the first preferred embodiment further includes a second ground conductor 25 and a protective film 27, the circuit board 100 is not necessarily required to include these features in order to provide the advantageous effects of the present invention. Alternatively, the circuit board 100 may include none of these features.

In the following description, the thickness direction of the substrate 10 is defined as the z-axis direction, and planes perpendicular or substantially perpendicular to the direction of the z-axis are defined by the x-axis and the y-axis.

The substrate 10 is a dielectric substrate having a plate shape. The substrate 10 includes substrate layers 10a and 10b laminated together in the thickness direction. The substrate 10 may be a substrate other than a multilayer substrate.

The first mounting conductor 21 is disposed on a surface of the substrate 10. The material of the first mounting conductor 21 is, for example, a foil of a metal such as copper or silver. The first mounting conductor 21 includes a first external connection conductor 26. In the thickness direction of the substrate 10, the first external connection conductor 26 is disposed on a surface of the first mounting conductor 21 opposite from a surface in contact with the surface of the substrate 10. The first external connection conductor 26 is a conductor including a metal. For example, the first external connection conductor 26 may be coated with a conductive joining material such as solder to connect to another electronic component.

The first external connection conductor 26 is, for example, a first plating conductor. The first plating conductor is formed by, for example, applying nickel plating and then applying gold plating over the nickel plating.

The first ground conductor 24 is disposed on the substrate 10 such that, in the thickness direction of the substrate 10, the first ground conductor 24 is located opposite to the first mounting conductor 21. In other words, in the thickness direction of the substrate 10, the first ground conductor 24 overlaps the first mounting conductor 21. According to the first preferred embodiment, the first ground conductor 24 is disposed on a surface of the substrate 10 opposite from the first mounting conductor 21 in the thickness direction of the substrate 10. The first ground conductor 24 is located opposite to the first external connection conductor 26 in the thickness direction of the substrate 10. The material of the first ground conductor 24 is, for example, a foil of a metal such as copper or silver. The first ground conductor 24 is connected to a ground potential. The first ground conductor 24 may be disposed inside the substrate 10.

The first floating conductor 22 is disposed inside the substrate 10. The first floating conductor 22 is disposed between the first mounting conductor 21 and the first ground conductor 24 in the thickness direction of the substrate 10. The first floating conductor 22 is not connected to another conductor. In other words, a substrate layer 10a or 10b is disposed between the first floating conductor 22 and such another conductor. The first floating conductor 22 overlaps the entire or substantially the entire first external connection conductor 26 when viewed in the thickness direction of the substrate 10.

The signal line conductor 20 is disposed inside the substrate 10. When viewed in the thickness direction of the substrate 10, the signal line conductor 20 is located at a position different from the first external connection conductor 26. The signal line conductor 20 is located opposite to the first ground conductor 24 in the thickness direction of the substrate 10. In other words, the signal line conductor 20 is disposed between the surface of the substrate 10, and the first ground conductor 24. The material of the signal line conductor 20 is, for example, a foil of a metal such as copper or silver. The signal line conductor 20 has a smaller width compared to the first external connection conductor 26.

In the thickness direction of the substrate 10, the second ground conductor 25 is disposed between the first ground conductor 24, and the surface of the substrate 10 on which the first mounting conductor 21 is disposed. The second ground conductor 25 includes an opening inside which the first external connection conductor 26 is located when viewed in the thickness direction of the substrate 10. According to the first preferred embodiment, when viewed in the thickness direction of the substrate 10, the second ground conductor 25 is disposed at a position different from the signal line conductor 20, the first floating conductor 22, and the first mounting conductor 21. In the thickness direction of the substrate 10, the first external connection conductor 26 is located inside the opening of the second ground conductor 25. The second ground conductor 25 is connected to a ground potential.

According to the first preferred embodiment, the signal line conductor 20, the first floating conductor 22, and the second ground conductor 25 are disposed at the same or substantially the same position in the thickness direction of the substrate 10. That is, the signal line conductor 20, the first floating conductor 22, and the second ground conductor 25 are disposed on the substrate layer 10b. Each of the signal line conductor 20, the first floating conductor 22, and the second ground conductor 25 may be disposed on a different substrate layer, or only one of these conductors may be disposed on a different layer.

As illustrated in FIG. 2, the connection conductor 23 electrically connects the signal line conductor 20 and the first mounting conductor 21 to each other. The connection conductor 23 extends through the substrate layer 10a in the thickness direction of the substrate 10. One end of the connection conductor 23 is in contact with the signal line conductor 20. The other end of the connection conductor 23 is in contact with the first mounting conductor 21. When viewed in the thickness direction of the substrate 10, the connection conductor 23 is disposed at a position different from the first external connection conductor 26.

The protective film 27 is disposed on the surface of the substrate 10 on which the first mounting conductor 21 is disposed. The protective film 27 protects the substrate 10. The protective film 27 includes an opening through which the first external connection conductor 26 is exposed. When viewed in the thickness direction of the substrate 10, the first floating conductor 22 overlaps an opening end portion of the protective film 27. As illustrated in FIG. 2, when viewed in the thickness direction of the substrate 10, the first external connection conductor 26 does not overlap the protective film 27. As illustrated in FIG. 3, when viewed in the thickness direction of the substrate 10, an end portion of at least a portion of the first external connection conductor 26 is exposed through the opening of the protective film 27. A portion of the substrate layer 10a may be exposed through the opening of the protective film 27 when viewed in the thickness direction of the substrate 10. In this case, as illustrated in FIG. 3, the respective exposed portions of the first external connection conductor 26 and the substrate layer 10a overlap the first floating conductor 22 when viewed in the thickness direction of the substrate 10. When viewed in the thickness direction of the substrate 10, the entire or substantially the entire first external connection conductor 26 may be exposed through the opening of the protective film 27. When viewed in the thickness direction of the substrate 10, an end portion in the direction of the plane of the first external connection conductor 26 may overlap the opening end portion of the protective film 27. The term end portion as used herein means an “edge” of the first external connection conductor 26, and does not mean a portion that includes the edge and the area in the vicinity of the edge.

The circuit board 100 configured as described above transmits a radio-frequency signal. In particular, the circuit board 100 transmits a radio-frequency signal through the signal line conductor 20, the first mounting conductor 21, and the connection conductor 23.

Manufacturing Method

The circuit board 100 according to the first preferred embodiment can be obtained through, for example, a manufacturing method described below.

The substrate layers 10a and 10b made of a dielectric material, for example, a ceramic material, thermosetting resin, or thermoplastic resin are prepared. Examples of the thermosetting resin include polyimide and epoxy glass. Examples of the thermoplastic resin include liquid crystal polymer and polytetrafluoroethylene (PTFE). A copper coil is applied onto one side of the substrate layers 10a and 10b, and then etching is performed to obtain the signal line conductor 20, the first mounting conductor 21, the first floating conductor 22, the first ground conductor 24, and the second ground conductor 25. The first external connection conductor 26 is obtained by, for example, applying nickel plating on the first mounting conductor 21 and then applying gold plating over the nickel plating. The connection conductor 23 is obtained by forming a through-hole in the substrate layer 10a, filling the through-hole with a conductive paste, and heating the conductive paste to allow the conductive paste to solidify. The substrate layers 10a and 10b are laminated together such as, for example, by being integrated with each other through hot pressing, or by being bonded to each other with adhesive. The protective film 27 is obtained by a method such as, for example, applying a paste having insulating properties, or sticking a sheet having insulating properties. The material of the protective film 27 differs in composition from the material of the substrate layers 10a and 10b such that, for example, LCP is used for one side and PI is used for the other side.

According to the first preferred embodiment, as illustrated in FIG. 2, the first ground conductor 24 is located opposite to the first mounting conductor 21 and the signal line conductor 20. However, the first ground conductor 24 is not necessarily located opposite to the signal line conductor 20. Another ground conductor connected to a ground potential may be located opposite to the signal line conductor 20.

As illustrated in FIG. 2, when viewed in the thickness direction of the substrate 10, the first mounting conductor 21 includes the following regions: a region A1 overlapping the connection conductor 23; a region A2 overlapping the first external connection conductor 26; and a region A3 located between the regions A1 and A2. When viewed in the thickness direction of the substrate 10, the first ground conductor 24 overlaps the region A1, the region A2 and the region A3, and the first floating conductor 22 overlaps the regions A2 and A3.

As illustrated in FIG. 4, the signal line conductor 20 and the first floating conductor 22 are spaced apart from each other by a distance L1. The second ground conductor 25 and the first floating conductor 22 are spaced apart from each other by a distance L2. In the circuit board 100, the distance L1 is less than the distance L2. A line segment connecting the center of the connection conductor 23 and the center of the first external connection conductor 26 has a dimension L3. The center of the connection conductor 23 is the intersection of the perpendicular or substantially perpendicular bisector of a line segment that has the maximum width in the X-direction, and the perpendicular or substantially perpendicular bisector of a line segment that has the maximum width in the Y-direction. In the direction connecting the center of the connection conductor 23 and the center of the first external connection conductor 26, the first floating conductor 22 has a dimension L4. In the circuit board 100, the dimension L3 is less than the dimension L4.

### Advantageous Effects

The circuit board 100 according to the first preferred embodiment provides the advantageous effect of reducing a decrease in the flatness of the first external connection conductor 26. The advantageous effect is described below in more specific detail.

The circuit board 100 makes it possible to reduce a decrease in the flatness of the first external connection conductor 26. More specifically, when viewed in the thickness direction of the substrate 10, the first floating conductor 22 overlaps the entire first external connection conductor 26. Consequently, in the direction of the plane of the substrate 10, a dielectric substrate adjacent to the first floating conductor 22 is disposed at a position different from the first external connection conductor 26 when viewed in the thickness direction of the substrate 10. Assuming that, when viewed in the thickness direction of the substrate 10, a dielectric substrate adjacent to the first floating conductor 22 overlaps the first external connection conductor 26, the resulting difference in conductor density may adversely affect the flatness of the first external connection conductor 26. Consequently, positioning the first floating conductor 22 to overlap the entire or substantially the entire first external connection conductor 26 when viewed in the thickness direction of the substrate 10 makes it possible to reduce a decrease in the flatness of the first external connection conductor 26.

With the circuit board 100, changing the size of the first floating conductor 22 makes it possible to adjust a stray capacitance generated between the first mounting conductor 21 and the first floating conductor 22. Since a radio-frequency signal flows through the first mounting conductor 21, adjusting the stray capacitance makes it possible to obtain suitable signal characteristics.

The circuit board 100 makes it possible to further reduce a decrease in the flatness of the first external connection conductor 26. More specifically, as illustrated in FIG. 2, the protective film 27 on the surface of the substrate 10 covers the end portion of the first mounting conductor 21. The first mounting conductor 21 is thus more securely fixed to the circuit board 100. As a result, a decrease in the flatness of the first mounting conductor 21 is reduced. This helps to further reduce a decrease in the flatness of the first external connection conductor 26 disposed on the first mounting conductor 21.

The circuit board 100 makes it possible to further reduce a decrease in the flatness of the first external connection conductor 26. More specifically, when viewed in the thickness direction of the substrate 10, an end portion of at least a portion of the first external connection conductor 26 is exposed through the opening of the protective film 27. A portion of the substrate layer 10a is exposed through the opening of the protective film 27 when viewed in the thickness direction of the substrate 10. In this case, as illustrated in FIG. 3, the respective exposed portions of the first external connection conductor 26 and the substrate layer 10a overlap the first floating conductor 22 when viewed in the thickness direction of the substrate 10. Accordingly, disposing the first floating conductor 22 over a wider area helps to further reduce in a decrease in the flatness of the first external connection conductor 26.

The circuit board 100 makes it possible to further reduce a decrease in the flatness of the first external connection conductor 26. More specifically, the signal line conductor 20 is disposed between the surface of the substrate 10, and the first ground conductor 24. Further, the first ground conductor 24 overlaps the first mounting conductor 21 in the thickness direction of the substrate 10. This helps to reduce in a decrease in the flatness of the first mounting conductor 21 in comparison to a case where the first ground conductor 24 overlaps only the first external connection conductor 26. That is, a decrease in the flatness of the first external connection conductor 26 can be further reduced.

The circuit board 100 enables adjustment of a capacitance generated by the first external connection conductor 26. More specifically, the signal line conductor 20 is disposed at the same or substantially the same position as the first floating conductor 22 in the thickness direction of the substrate 10. This helps to reduce an increase in the capacitance generated by the first external connection conductor 26, in comparison to a case where a ground conductor is provided instead of the first floating conductor 22. Conductors disposed at the same or substantially the same position in the thickness direction of the substrate 10 tend to have the same or substantially the same thickness. Consequently, in the thickness direction of the substrate 10, a decrease in the flatness of the first mounting conductor 21 can be reduced. That is, a decrease in the flatness of the first external connection conductor 26 can be further reduced.

The circuit board 100 makes it possible to further reduce a decrease in the flatness of the first external connection conductor 26. More specifically, the second ground conductor 25 is disposed at the same or substantially the same position as the signal line conductor 20 and the first floating conductor 22 in the thickness direction of the substrate 10. Conductors disposed at the same or substantially the same position in the thickness direction of the substrate 10 tend to have the same or substantially the same thickness. Consequently, in the thickness direction of the substrate 10, a decrease in the flatness of the substrate 10 can be reduced. That is, a decrease in the flatness of each of the first mounting conductor 21 and the first external connection conductor 26 can be further reduced.

The circuit board 100 enables adjustment of a capacitance generated by the first mounting conductor 21. More specifically, the distance L1 between the signal line conductor 20 and the first floating conductor 22 is less than the distance L2 between the second ground conductor 25 and the first floating conductor 22. This helps to reduce an increase in the stray capacitance generated via the first floating conductor 22 between the first mounting conductor 21 and the second ground conductor 25.

The circuit board 100 makes it possible to further reduce a decrease in the flatness of the first external connection conductor 26. More specifically, the dimension L3 of the line segment connecting the center of the connection conductor 23 and the center of the first external connection conductor 26 is less than the dimension L4 of the first floating conductor 22 in the direction connecting the center of the connection conductor 23 and the center of the first external connection conductor 26. That is, the first floating conductor 22 overlaps a relatively large portion of the first mounting conductor 21 in the thickness direction of the substrate 10. This helps to reduce a decrease in the flatness of the first mounting conductor 21. That is, a decrease in the flatness of the first external connection conductor 26 can be further reduced.

The circuit board 100 makes it possible to further reduce a decrease in the flatness of the first external connection conductor 26. More specifically, as illustrated in FIG. 2, the first floating conductor 22 is located in the regions A2 and A3. That is, the first floating conductor 22 overlaps a relatively large portion of the first mounting conductor 21 in the thickness direction of the substrate 10. This helps to reduce a decrease in the flatness of the first mounting conductor 21. That is, a decrease in the flatness of the first external connection conductor 26 can be further reduced.

The circuit board 100 makes it possible to reduce a decrease in the flatness of the first external connection conductor 26. More specifically, due to the tendency of thermoplastic resin to deform under heat, using thermoplastic resin as the material of the substrate layers 10a and 10b makes it more difficult to reduce a decrease in the flatness of the first mounting conductor 21, in comparison to using other materials. Accordingly, using the configuration described above helps to further reduce a decrease in the flatness of the first external connection conductor 26.

The circuit board 100 makes it possible to reduce poor connection between the first external connection conductor 26 and another electronic component. More specifically, the first external connection conductor 26 can be coated with, for example, a conductive joining material such as solder to connect to another electronic component. That is, the other electronic component is connected to the first mounting conductor 21 via the conductive joining material such as solder, for example. The conductive joining material such as solder is used in a softened condition to join two portions together. Accordingly, when the conductive joining material such as solder is to be used, if the area to be coated with the conductive joining material has decreased flatness, this may result in poor connection between a portion to be joined and the conductive joining material. Therefore, when the conductive joining material such as solder is to be used, reducing a decrease in the flatness of the first external connection conductor 26 leads to a reduction of poor connection between the first external connection conductor 26 and the other electronic component.

The signal line conductor 20 may be disposed at a position different from the first floating conductor 22 in the thickness direction of the substrate 10.

The dimension L3 of the line segment connecting the center of the connection conductor 23 and the center of the first external connection conductor 26 may be greater than the dimension L4 of the first floating conductor 22 in the direction connecting the center of the connection conductor 23 and the center of the first external connection conductor 26.

When viewed in the thickness direction of the substrate 10, a ground conductor different from the first ground conductor 24 may overlap the following regions: the region A1 overlapping the connection conductor 23; the region A2 overlapping the first external connection conductor 26; and the region A3 located between the regions A1 and A2. The first floating conductor 22 may not overlapping with the region A3.

A metal plate such as, for example, a SUS plate may be disposed at a position that overlaps the first floating conductor 22 when viewed in the thickness direction. This further improves the flatness of the first external connection conductor 26.

In the circuit board 100, the signal line conductor 20 has a smaller width compared to the first external connection conductor 26. In other words, the first external connection conductor 26 has a larger width compared to the signal line conductor 20. Assuming that the circuit board 100 includes no first floating conductor 22, and the second ground conductor 25 overlaps the first external connection conductor 26 when viewed in the thickness direction of the substrate 10, such a configuration results in increased capacitance per unit area generated by the first external connection conductor 26, relative to the signal line conductor 20. In this case, assuming that the second ground conductor 25 includes an opening that overlaps the first external connection conductor 26 when viewed in the thickness direction of the substrate 10, and no first floating conductor 22 is provided, such a configuration mitigates the increase in the capacitance generated. However, the resulting non-uniformity in conductor density leads to deterioration of the overall flatness of the circuit board 100. By contrast, if, as with the first preferred embodiment, the circuit board 100 includes the first floating conductor 22, and the second ground conductor 25 includes an opening that overlaps the first external connection conductor 26 when viewed in the thickness direction of the substrate 10, such a configuration is advantageous both with respect to the increase in the capacitance generated and to flatness.

First Modification

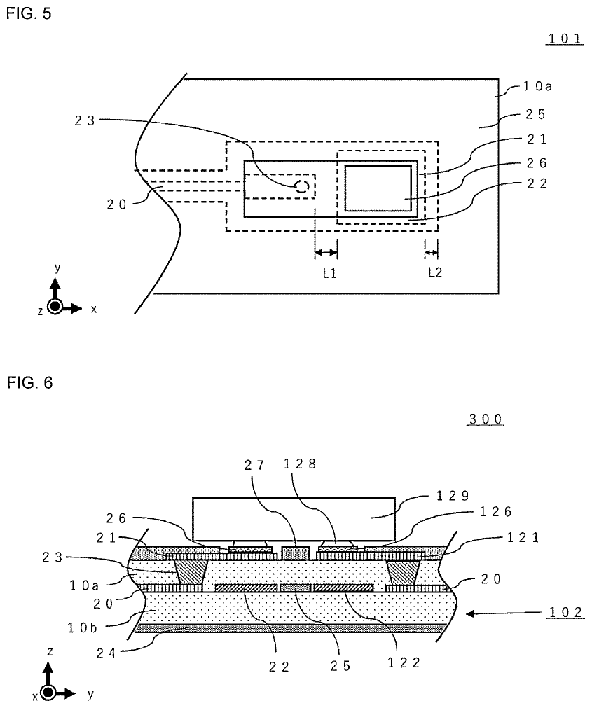

A circuit board 101 according to a first modification of a preferred embodiment of the present invention is described below with reference to the drawings. FIG. 5 is a partial enlarged view of the circuit board 101.

The circuit board 101 differs from the circuit board 100 in terms of the distance L1 between the signal line conductor 20 and the first floating conductor 22, and the distance L2 between the second ground conductor 25 and the first floating conductor 22. More specifically, the distance L1 between the signal line conductor 20 and the first floating conductor 22 is greater than the distance L2 between the second ground conductor 25 and the first floating conductor 22.

Consequently, the first floating conductor 22 is disposed at a comparatively large distance from the signal line conductor 20. This helps to reduce a decrease in the flatness of the first external connection conductor 26.

More specifically, the connection conductor 23 is made of a conductive paste. Accordingly, depending on the method of heating or solidifying the connection conductor 23, irregularities can occur on the surface of the connection conductor 23. Since the first mounting conductor 21 is connected to the connection conductor 23, such irregularities in the connection conductor 23 may cause irregularities to occur in a region of the first mounting conductor 21 that is in contact with the connection conductor 23 when viewed in the thickness direction of the substrate 10. In the circuit board 101, the first floating conductor 22 is disposed at a comparatively large distance from the signal line conductor 20. In other words, when viewed in the thickness direction of the substrate 10, the first external connection conductor 26 is disposed at a comparatively large distance from the region of the first mounting conductor 21 that is in contact with the connection conductor 23. This helps to reduce a decrease in the flatness of the first external connection conductor 26.

### Second Preferred Embodiment

Each of the circuit board 100 and the circuit board 101 to which another component 129 has been mounted can be used as an electronic component 300. The electronic component 300 is used in, for example, an electronic apparatus such as a smartphone to electrically connect two circuits to each other.

The electronic component 300 according to a second preferred embodiment of the present invention is described below with reference to the drawings. FIG. 6 is a partial cross-sectional view of the electronic component 300.

The electronic component 300 includes a circuit board 102 to which the other component 129 has been mounted. The circuit board 102 differs from the circuit board 100 in that a second mounting conductor 121 and a second floating conductor 122 are provided, and in the positioning of the first floating conductor 22 and the second ground conductor 25.

The second mounting conductor 121 is disposed on the surface of the substrate 10. The material of the second mounting conductor 121 is, for example, a foil of a metal such as copper or silver. The second mounting conductor 121 includes a second external connection conductor 126. In the thickness direction of the substrate 10, the second external connection conductor 126 is disposed on a surface of the second mounting conductor 121 opposite from a surface in contact with the surface of the substrate 10. The second external connection conductor 126 includes a metal. The second external connection conductor 126 can be coated with, for example, a conductive joining material such as solder to connect to another electronic component.

The second external connection conductor 126 is, for example, a second plating conductor. The second plating conductor is formed by, for example, applying nickel plating and then applying gold plating over the nickel plating.

The second mounting conductor 121 is connected via the connection conductor 23 to a conductor pattern made of a metal foil or other material. In the electronic component 300, the conductor pattern made of a metal foil or other material is another signal line conductor 20 different from the signal line conductor 20 that is electrically connected to the first mounting conductor 21. The same or substantially the same radio-frequency signal may flow through the two signal line conductors 20. Alternatively, different signals may flow through the signal line conductors 20, such that a radio-frequency signal flows through one of the two signal line conductors 20 and an analog signal flows through the other of the two signal line conductors 20.

The second floating conductor 122 is disposed inside the substrate 10. The second floating conductor 122 is disposed between the second mounting conductor 121 and the first ground conductor 24 in the thickness direction of the substrate 10. The second floating conductor 122 is not connected to a ground potential or the signal line conductor 20. The second floating conductor 122 overlaps at least a portion of the second external connection conductor 126 when viewed in the thickness direction of the substrate 10. In the electronic component 300, the second floating conductor 122 overlaps the entire or substantially the entire second external connection conductor 126 when viewed in the thickness direction of the substrate 10. The second floating conductor 122 is disposed at the same or substantially the same position as the first floating conductor 22 in the thickness direction of the substrate 10.

The second ground conductor 25 is further disposed at a position between the first floating conductor 22 and the second floating conductor 122, in addition to the position where the second ground conductor 25 is disposed in the circuit board 100.

The other component 129 is connected to each of the first external connection conductor 26 and the second external connection conductor 126 via a conductive joining material such as solder.

The electronic component 300 makes it possible to reduce tilting of the other component 129. More specifically, when viewed in the thickness direction of the substrate 10, the second floating conductor 122 overlaps at least a portion of the second external connection conductor 126. The other component 129 is connected to the first external connection conductor 26 and the second external connection conductor 126. As with the circuit board 100, the configuration described above helps to reduce a decrease in the flatness of the other component 129.

As described above, the second floating conductor 122 overlaps the entire or substantially the entire second external connection conductor 126 when viewed in the thickness direction of the substrate 10. This helps to further reduce a decrease in the flatness of the other component 129.

As described above, the second floating conductor 122 is disposed at the same or substantially the same position as the first floating conductor 22 in the thickness direction of the substrate 10. The first floating conductor 22 and the second floating conductor 122 thus tend to have the same or substantially the same thickness, which helps to further reduce a decrease in the flatness of the other component 129.

As described above, the second ground conductor 25 is further disposed at the position between the first floating conductor 22 and the second floating conductor 122, in addition to the position where the second ground conductor 25 is disposed in the circuit board 100. The first floating conductor 22 and the second floating conductor 122 thus tend to have the same or substantially the same thickness as the second ground conductor 25, which helps to further reduce a decrease in the flatness of the other component 129.

In the electronic component 300, a decrease in the flatness of the first external connection conductor 26 may conceivably result in poor connection between a portion to be joined and a conductive joining material. Accordingly, for the electronic component 300 using a conductive joining material such as solder, for example, reducing a decrease in the flatness of the first external connection conductor 26 leads to reduction of poor connection between the first external connection conductor 26 and the other component 129.

Second Modification

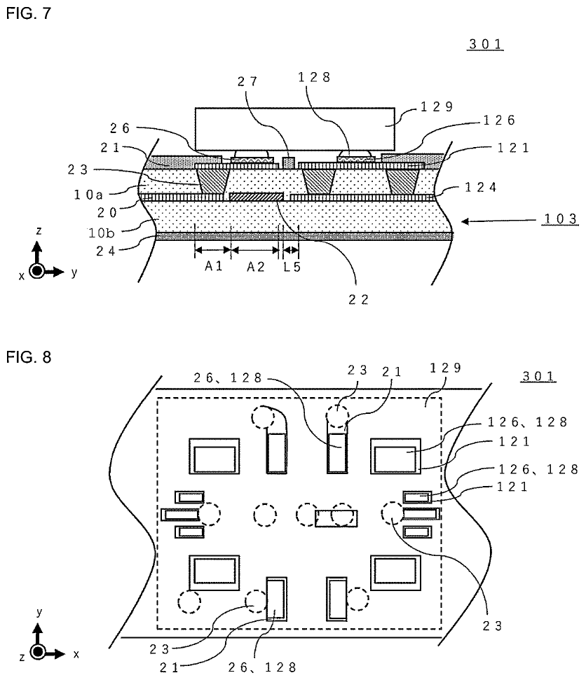

An electronic component 301 according to a second modification of a preferred embodiment of the present invention is described below with reference to the drawings. FIG. 7 is a partial cross-sectional view of the electronic component 301. FIG. 8 is a partial cross-sectional view of the electronic component 301.

The electronic component 301 includes a circuit board 103 to which the other component 129 has been mounted. The circuit board 103 differs from the circuit board 100 in that an additional connection conductor 23 and a third ground conductor 124 are provided, and in the positioning of individual features.

As illustrated in FIG. 7, when viewed in the thickness direction of the substrate 10, the first mounting conductor 21 includes the region A1, which overlaps the connection conductor 23, and the region A2, which overlaps the first external connection conductor 26, and these regions are in contact with each other. The second mounting conductor 121 is connected to a ground potential. The second mounting conductor 121 is connected to the second ground conductor 124 via the connection conductor 23.

The second external connection conductor 126 overlaps the third ground conductor 124 when viewed in the thickness direction of the substrate 10.

As illustrated in FIG. 8, the electronic component 301 may include multiple connection conductors 23. When viewed in the thickness direction of the substrate 10, the region overlapping each of the connection conductors 23 and the region overlapping the first external connection conductor 26 may not be in contact with each other. Each of the connection conductors 23 may transmit the same or substantially the same signal, or may transmit a different signal. For example, as illustrated in FIG. 7, the connection conductors 23 may be divided to those connection conductors 23 that are connected to a ground conductor such as the third ground conductor 124, and those connection conductors 23 that are connected to the signal line conductor 20.

To avoid complexity of illustration, the other component 129 is represented by a dashed line in FIG. 8. The other component 129 is mounted on, for example, the surface of the substrate 10 as illustrated in FIG. 7.

The electronic component 301 makes it possible to reduce a decrease in the flatness of the first external connection conductor 26. More specifically, when viewed in the thickness direction of the substrate 10, the electronic component 301 includes the region overlapping the connection conductor 23, and the region overlapping the first external connection conductor 26, and these regions are in contact with each other. This results in reduced distance between the signal line conductor 20 and the first floating conductor 22, which helps to reduce a decrease in the flatness of the first mounting conductor 21. That is, a decrease in the flatness of the first external connection conductor 26 can be reduced.

It is more preferable if, when viewed in the thickness direction, a spacing L5 is provided between the first floating conductor 22 and the second mounting conductor 121. This helps to reduce a shift in ground potential for the second mounting conductor 121.

Third Modification

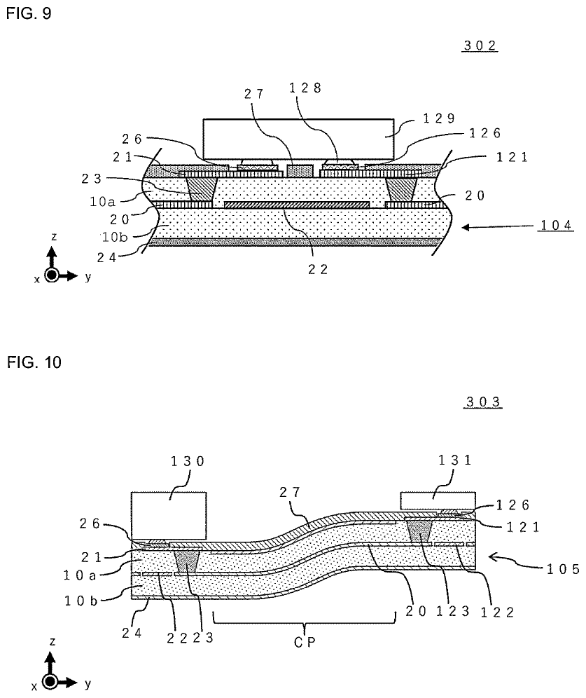

An electronic component 302 according to a third modification of a preferred embodiment of the present invention is described below with reference to the drawings. FIG. 9 is a partial cross-sectional view of the electronic component 302.

The electronic component 302 includes a circuit board 104 to which the other component 129 has been mounted. The circuit board 104 differs from the circuit board 102 in that the first floating conductor 22 and the second floating conductor 122 are made of the same single conductor.

When viewed in the thickness direction of the substrate 10, the first floating conductor 22 is disposed continuously so as to overlap the first external connection conductor 26 and the second external connection conductor 126.

The electronic component 302 makes it possible to reduce a decrease in the flatness of the first external connection conductor 26. More specifically, when viewed in the thickness direction of the substrate 10, the first floating conductor 22 is disposed continuously so as to overlap the first external connection conductor 26 and the second external connection conductor 126. The first floating conductor 22 is thus disposed over a wider area, which helps to reduce a decrease in the flatness of the first external connection conductor 26. Further, as with the electronic component 300, tilting of the other component 129 can be reduced.

The second external connection conductor 126 and the first external connection conductor 26 may be made of the same material or, as long as advantageous effects the same as or similar to those of preferred embodiments of the present invention are obtained, may be made of different materials. Further, the third ground conductor 124 and the first ground conductor 24 may be made of the same material or, as long as advantageous effects the same as or similar to those of preferred embodiments of the present invention are obtained, may be made of different materials.

The connection conductor 23 may electrically connect the signal line conductor 20 and the first mounting conductor 21 to each other via another connection conductor that overlaps the connection conductor 23 when viewed in the thickness direction of the substrate 10.

In addition to the first mounting conductor 21, another ground conductor not overlapping the first mounting conductor 21 when viewed in the thickness direction of the substrate 10 may be disposed on the surface of the substrate layer 10a. In a region where a signal line is disposed between the other ground conductor and the first ground conductor 24, a stripline structure is defined.

Another conductor may be disposed at a position that overlaps the entire or substantially the entire first external connection conductor 26 when viewed in the thickness direction of the substrate 10. As such another conductor overlaps the second external connection conductor 126 when viewed in the thickness direction of the substrate 10, a decrease in the flatness of the first external connection conductor 26 can be reduced. In other words, if, when viewed in the thickness direction of the substrate 10, the number of conductors overlapping the entire or substantially the entire first external connection conductor 26 and the number of conductors overlapping the second external connection conductor 126 are the same, a decrease in the flatness of the first external connection conductor 26 can be reduced.

### Third Preferred Embodiment

Each of the circuit boards and the electronic components described above may include a bent portion. An electronic component 303 illustrated in FIG. 10 is used in, for example, an electronic apparatus such as a smartphone to electrically connect two circuits having different thicknesses to each other.

An electronic component 303 according to a third preferred embodiment of the present invention is described below with reference to the drawings. FIG. 10 is a partial cross-sectional view of the electronic component 303.

The electronic component 303 includes a circuit board 105 to which another component 130 and another component 131 have been mounted. The circuit board 105 differs from the circuit board 100 in that a bent portion CP is provided.

The bent portion CP is disposed at a position overlapping the signal line conductor 20. In the bent portion CP, the substrate layers 10a and 10b and the signal line conductor 20 are bent with respect to the thickness direction. Although the bent portion CP is illustrated in FIG. 10 as being bent in the thickness direction such that the right-hand side region of the circuit board 105 is positioned higher than the left-hand side region, the bent portion CP may be bent in a different direction.

When viewed in the thickness direction of the substrate 10, the first floating conductor 22 overlaps at least a portion of the first external connection conductor 26. When viewed in the thickness direction, the first floating conductor 22 does not overlap the bent portion CP. Similarly, when viewed in the thickness direction of the substrate 10, the second floating conductor 122 overlaps at least a portion of the second external connection conductor 126. When viewed in the thickness direction, the second floating conductor 122 does not overlap the bent portion CP.

The other components 130 and 131 are respectively connected to the first external connection conductor 26 and the second external connection conductor 126 via a conductive joining material such as solder. The first external connection conductor 26 is connected to the signal line conductor 20 via the first mounting conductor 21 and first the connection conductor 23. Likewise, the second external connection conductor 126 is connected to the signal line conductor 20 via the second mounting conductor 121 and a second connection conductor 123.

The electronic component 303 makes it possible to reduce tilting of the other components 130 and 131.

More specifically, when viewed in the thickness direction of the substrate 10, the first floating conductor 22 overlaps at least a portion of the first external connection conductor 26. The other component 130 is connected to the first external connection conductor 26. As with the circuit board 100, the configuration described above helps to reduce a decrease in the flatness of each of the other components 130 and 131.

The electronic component 303 makes it possible to reduce tilting of the other components 130 and 131. More specifically, when viewed in the thickness direction, the first floating conductor 22 does not overlap the bent portion CP. Stress generated in the bent portion CP is thus less likely to be transmitted to the first floating conductor 22. This helps to reduce tilting of the other components 130 and 131.

To avoid complexity of illustration, the protective film 27 is not illustrated in FIGS. 1, 4, 5, and 8.

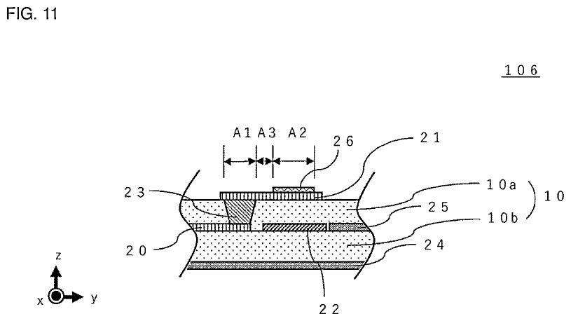

FIG. 11 is a partial cross-sectional view of a circuit board 106 according to a preferred embodiment of the present invention. The circuit board 106 differs from the circuit board 100 in that the circuit board 106 does not include the protective film 27. The circuit board 106 makes it possible to reduce a decrease in the flatness of the first external connection conductor 26. As with the circuit board 106, according to the preferred embodiments and modifications thereof, the protective film is not necessarily required to be provided.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A circuit board comprising:
a substrate;
a first mounting conductor located on a surface of the substrate and including a first external connection conductor;
a first ground conductor located on the substrate and opposite to the first mounting conductor;
a second ground conductor between the surface of the substrate and the first ground conductor;
a floating conductor between the first mounting conductor and the first ground conductor;
a signal line conductor inside the substrate; and
a connection conductor connecting the first mounting conductor and the signal line conductor to each other; wherein
when viewed in a thickness direction of the substrate, the signal line conductor and the connection conductor are each located at a position different from the first external connection conductor, and the floating conductor overlaps an entirety or substantially an entirety of the first external connection conductor;
the second ground conductor includes an opening inside of which the first external connection conductor is located when viewed in the thickness direction; and
when viewed in the thickness direction, the floating conductor and the signal line conductor have a spacing between each other that is less than a spacing between the floating conductor and the second ground conductor.

2. The circuit board according to claim 1, further comprising a protective film.

3. The circuit board according to claim 2, wherein
when viewed in the thickness direction of the substrate, the protective film includes an opening having a size greater than or equal to a size of the first external connection conductor; and
when viewed in the thickness direction of the substrate, the first external connection conductor is surrounded by the protective film.

4. The circuit board according to claim 1, wherein the first external connection conductor and the floating conductor overlap an opening end portion of the protective film.

5. The circuit board according to claim 3, wherein an end portion of at least a portion of the first external connection conductor is exposed through the opening.

6. The circuit board according to claim 1, wherein
the first ground conductor is located opposite to the signal line conductor; and
the signal line conductor is between the surface of the substrate and the first ground conductor.

7. The circuit board according to claim 1, wherein, in the thickness direction, the signal line conductor is provided at a same or substantially a same position as the floating conductor.

8. The circuit board according to claim 1, wherein, in the thickness direction, the second ground conductor is provided at a same position as the signal line conductor.

9. The circuit board according to claim 1, wherein, in a direction connecting a center of the connection conductor and a center of the first external connection conductor, the floating conductor has a dimension greater than a dimension of a line segment connecting the center of the connection conductor and the center of the first external connection conductor.

10. The circuit board according to claim 1, wherein
the first mounting conductor includes a first region, a second region, and a third region, the first region being a region where the first external connection conductor is provided, the second region being connected to the connection conductor, the third region being located between the first region and the second region; and
the floating conductor overlaps the third region.

11. The circuit board according to claim 1, wherein
the first mounting conductor includes a first region and a second region, the first region being a region where the first external connection conductor is provided, the second region being connected to the connection conductor; and
the first region and the second region are in contact with each other.

12. The circuit board according to claim 1, further comprising:
a second mounting conductor on the surface of the substrate, the second mounting conductor including a second external connection conductor; and
another conductor at a same or substantially a same position as the floating conductor in the thickness direction; wherein
the first ground conductor is located opposite to the second mounting conductor; and
when viewed in the thickness direction, the another conductor overlaps at least a portion of the second external connection conductor.

13. The circuit board according to claim 12, wherein when viewed in the thickness direction, the other conductor overlaps an entirety of the second external connection conductor.

14. The circuit board according to claim 12, wherein the floating conductor and the another conductor are defined by a single conductor.

15. The circuit board according to claim 12, wherein the another conductor is a third ground conductor.

16. The circuit board according to claim 12, wherein the first external connection conductor and the second external connection conductor are connected to a single component.

17. The circuit board according to claim 1, wherein the substrate is made mainly of resin.

18. The circuit board according to claim 1, wherein the substrate further includes a conductive joining material joined to the first external connection conductor.

19. The circuit board according to claim 1, wherein the substrate includes thermoplastic resin.

20. A circuit board comprising:
a substrate;
a first mounting conductor located on a surface of the substrate and including a first external connection conductor;
a first ground conductor located on the substrate and opposite to the first mounting conductor;
a second ground conductor between the surface of the substrate and the first ground conductor;
a floating conductor between the first mounting conductor and the first ground conductor;
a signal line conductor inside the substrate; and
a connection conductor connecting the first mounting conductor and the signal line conductor to each other; wherein
when viewed in a thickness direction of the substrate, the signal line conductor and the connection conductor are each located at a position different from the first external connection conductor, and the floating conductor overlaps an entirety or substantially an entirety of the first external connection conductor;
the second ground conductor includes an opening inside of which the first external connection conductor is located when viewed in the thickness direction; and
when viewed in the thickness direction, the floating conductor and the signal line conductor have a spacing between each other that is greater than a spacing between the floating conductor and the second ground conductor.

21. An electronic component comprising:
the circuit board according to claim 1; and
a component on or above the circuit board; wherein
the component is connected to the first external connection conductor of the circuit board via a conductive joining material.

22. An electronic component comprising:
the circuit board according to claim 20; and
a component on or above the circuit board; wherein
the component is connected to the first external connection conductor of the circuit board via a conductive joining material.
